(19) United States
(12) Patent Application Publication
(10) Pub. No.: US 2026/0120351 A1
(43) Pub. Date: Apr. 30, 2026

(54) DRAWING PROCESSING DEVICE AND DRAWING PROCESSING METHOD

(71) Applicant: REVOX Corporation, Shizuoka-shi, Shizuoka (JP)

(72) Inventors: Cam Hao Phung, Yaizu-shi, Shizuoka (JP); Hiroshi Shikanai, Yaizu-shi, Shizuoka (JP)

(73) Assignee: REVOX Corporation, Shizuoka-shi, Shizuoka (JP)

(21) Appl. No.: 19/116,824

(22) PCT Filed: Aug. 26, 2024
(86) PCT No.: PCT/JP2024/030202

§ 371 Date: Mar. 28, 2025

(30) Foreign Application Priority Data
Apr. 3, 2024 (JP) 2024-059906

(51) Int. Cl. G06T 11/26; G06F 30/12; G06T 5/50

(52) U.S. Cl. CPC G06T 11/26; G06F 30/12; G06T 5/50; G06T 2207/20221

(57) ABSTRACT

Problem: To provide a drawing processing device that enables easy visualization of differences when two pieces of drawing data are compared.

Solution to Problem: A drawing processing device includes a request reception unit (204) configured to receive a comparison request for comparing reference drawing data (D10A) being drawing data that serves as a reference and comparison drawing data (D10B) being drawing data to be compared to the reference drawing data (D10A), and identifies a reference drawing area (10-1A to 10-3A) surrounding a drawing element (11-1A to 11-3A) included in the reference drawing data (D10A) of the comparison request received by the request reception unit (204) and a comparison drawing area (10-1B to 10-3B) surrounding a drawing element (11-1B to 11-3B) included in the comparison drawing data (D10B) of the comparison request received by the request reception unit (204), thereby generates drawing display information (D12) for displaying the identified reference drawing area (10-1A to 10-3A) and comparison drawing area (10-1B to 10-3B) in a superimposed manner.

### TECHNICAL FIELD

The present invention relates to a drawing processing device and a drawing processing method.

### BACKGROUND OF INVENTION

Drawings used in various industries, such as machinery, construction, civil engineering, electricity, and apparel are generally registered and managed in a database as drawing data. For example, Patent Document 1 discloses a parts drawing management system in which individual pieces of drawing data are registered in a database with assigned names and attributes such that a user can search for desired drawing data.

### PRIOR ART

### Patent Literature

Patent Document 1: JP 2008-059474 A

### SUMMARY OF INVENTION

### Problem to be Solved by Invention

In the parts drawing management system disclosed in Patent Document 1, a user searches for desired drawing data by specifying the name or attribute of the data, and the drawing data is displayed as search results. If, for example, two drawings are retrieved as the search results, the user has no choice but to compare the drawings to check differences in shapes and dimensions of the parts between the two drawings. However, it is difficult for the user to intuitively understand differences when comparing two pieces of drawing data, and the differences may be overlooked.

The present invention was made in view of the above problem, and an object of the present invention is to provide a drawing processing device and a drawing processing method that enable easy visualization of differences when two pieces of drawing data are compared.

### Means for Solving the Problem

In order to achieve the object described above, a drawing processing device according to an aspect of the present invention is a drawing processing device for processing drawing data including one or more drawing elements that specify a shape or dimensions of a target object, the drawing processing device including:
a request reception unit configured to receive a comparison request for comparing reference drawing data being the drawing data that serves as a reference and comparison drawing data being the drawing data to be compared to the reference drawing data; and
a display information generation unit configured to identify a reference drawing area surrounding the drawing element included in the reference drawing data of the comparison request received by the request reception unit and a comparison drawing area surrounding the drawing element included in the comparison drawing data of the comparison request received by the request reception unit, to thereby generate drawing display information for displaying the identified reference drawing area and the identified comparison drawing area in a superimposed manner.

### Effect of the Invention

With the drawing processing device according to an aspect of the present invention, a reference drawing area surrounding a drawing element included in reference drawing data and a comparison drawing area surrounding a drawing element included in comparison drawing data are identified, and drawing display information is generated in which the reference drawing area and the comparison drawing area are superimposed such that differences between the two drawing data can be easily seen when the two drawing data are compared.

Problems, configurations, and effects other than those described above will become clear in the following description of the embodiments for implementing the present invention.

### BRIEF DESCRIPTION OF THE DRAWINGS

FIG. 1 is an overall configuration diagram showing an example of a drawing management system 1.

FIG. 2A is a diagram showing a first example of drawing data D10.

FIG. 2B is a diagram showing a second example of drawing data D10.

FIG. 3 is a diagram showing an example of a drawing database 210.

FIG. 4 is a block diagram showing an example of a drawing processing device 2.

FIG. 5 is a functional illustration of an example of a request reception unit 204 and a display information generation unit 205.

FIG. 6 is a hardware configuration diagram showing an example of a computer 900.

FIG. 7 is a flowchart showing a first operation example of a drawing processing method performed by the drawing processing device 2.

FIG. 8A is a diagram showing a first display example of a drawing comparison screen 13A.

FIG. 8B is a diagram showing a second display example of a drawing comparison screen 13B.

FIG. 9 is a flowchart showing a second operation example of the drawing processing method performed by the drawing processing device 2.

### EMBODIMENTS FOR IMPLEMENTING THE INVENTION

The following is a description of embodiments for implementing the present invention with reference to the drawings. In the following description, the scope necessary for explanation to achieve the object of the present invention will be described schematically, explanation will focus on the scope necessary for the explanation of relevant parts of the present invention, and any parts that are omitted shall be based on the known art.

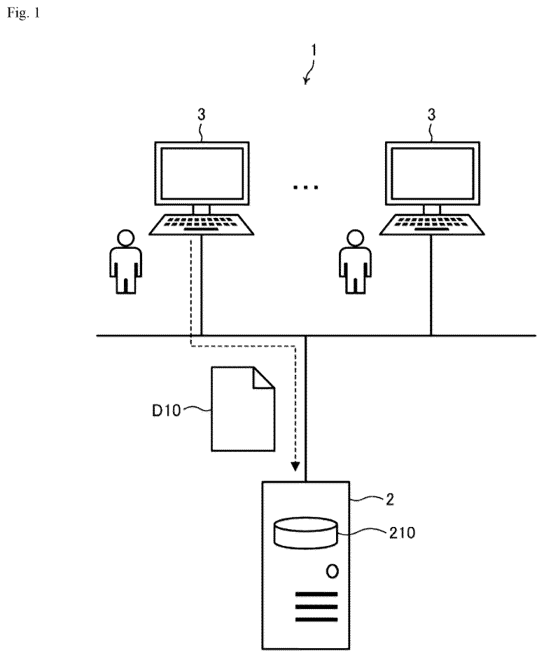

FIG. 1 is an overall configuration diagram showing an example of a drawing management system 1. The drawing management system 1 functions as a system that manages drawing data D10.

The drawing data D10 handled by the drawing management system 1 is, for example, any type of drawing recorded as digital data, such as assembly drawings and parts drawings for mechanical drawings, architectural drawings, electrical circuit diagrams, pneumatic circuit diagrams, hydraulic circuit diagrams, and apparel drawings. In this case, the drawing data D10 can be either vector-format data or raster-format data. For example, the drawing data D10 can be CAD data (an example of the vector-format data) output by any type of CAD software, or image data (an example of the raster-format data) output by scanning a drawing printed on paper media. Furthermore, the drawing data D10 can be created using any projection method and can be three-dimensional.

As shown in FIG. 1, the drawing management system 1 includes a drawing processing device 2 and a user terminal device 3. The drawing processing device 2 and the user terminal device 3 are connected to a wired or wireless network 4 and are configured to mutually send and receive various types of data. The number of drawing processing devices 2 and user terminal devices 3 and the connection configuration of these devices with the network 4 are not limited to the example shown in FIG. 1 and may be changed as required.

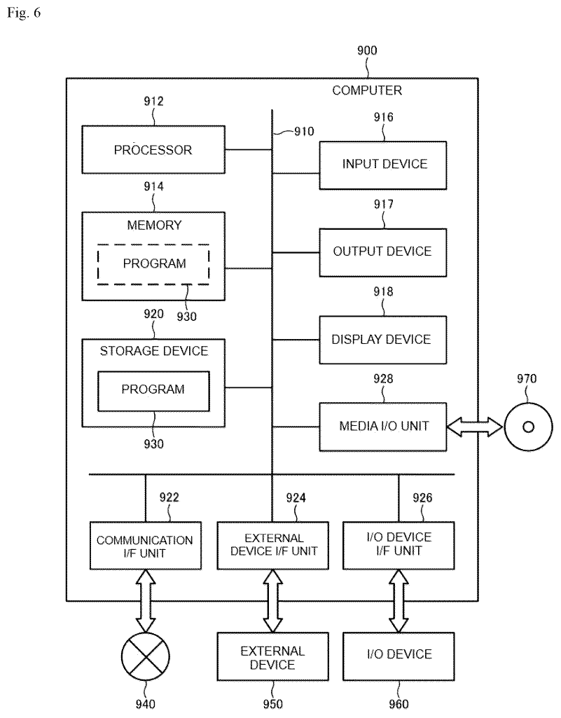

The drawing processing device 2 is a server-type computer or a cloud-type computer, and is composed of a general-purpose computer or a dedicated computer (see FIG. 6 described below), for example. The drawing processing device 2 includes a drawing database 210 that can register the drawing data D10 and incidental information (details will be provided below) included in the drawing data D10 in association with each other.

The drawing processing device 2 receives new drawing data D10 from the user terminal device 3, acquires the incidental information included in the drawing data D10, and registers the drawing data D10 and the incidental information in the drawing database 210. Further, the drawing processing device 2 references the (existing) drawing data D10 and incidental information registered in the drawing database 210 and provides display information for editing or the like to the user terminal device 3.

The user terminal device 3 is a client-type computer and is composed of a general-purpose computer or a dedicated computer (see FIG. 6 described below), for example. The user terminal device 3 receives various input operations via a display screen, such as an application or a browser, such that a user can register new drawing data D10, reference existing drawing data D10, or edit the drawing data D10, and outputs various information via the display screen or sound.

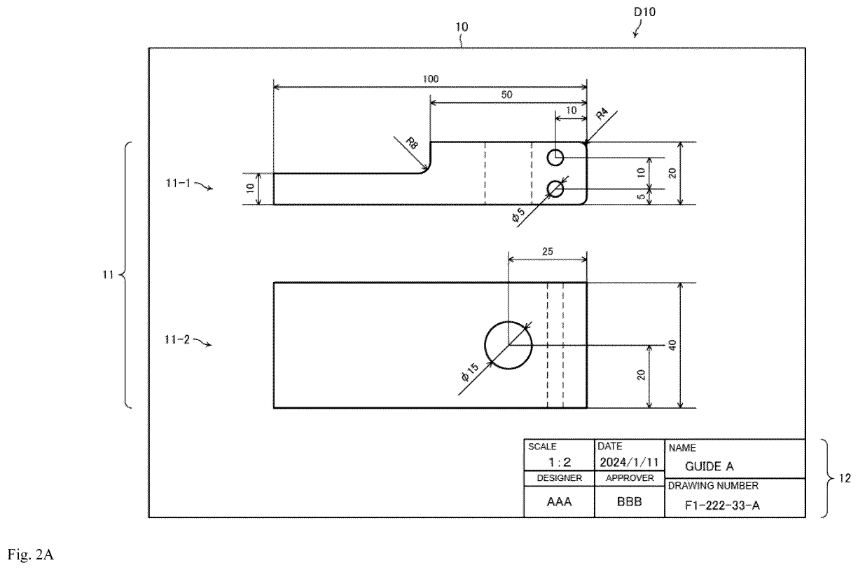

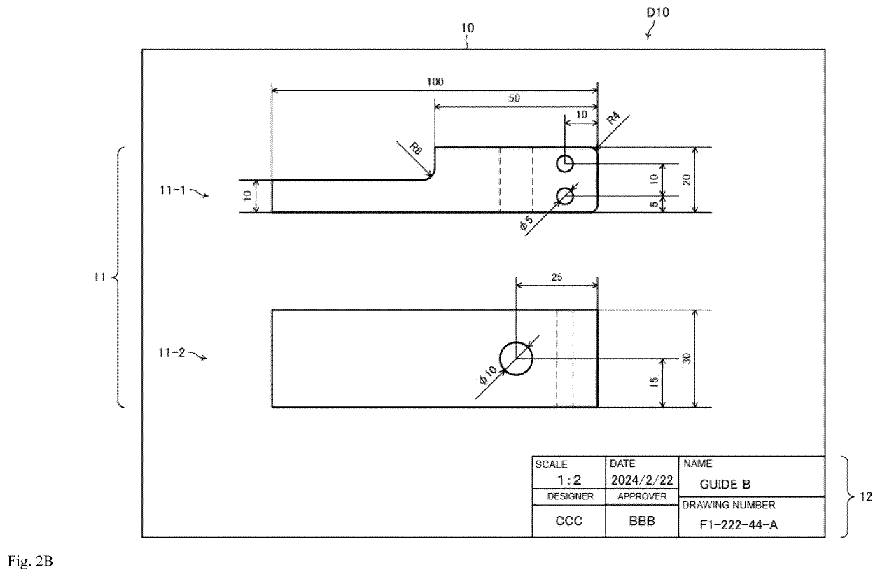

FIG. 2A is a diagram showing a first example of the drawing data D10. FIG. 2B is a diagram showing a second example of the drawing data D10. The drawing data D10 shown in FIGS. 2A and 2B are parts diagrams that represent parts with some different shapes and dimensions. This embodiment will focus on a case where, as shown in FIGS. 2A and 2B, the drawing data D10 is a parts diagram.

The drawing data D10 includes one or more drawing elements 11 that specify the shape and dimensions of an object. An entire area 10 of the drawing data D10 shown in FIGS. 2A and 2B contains a title field 12 and two drawing elements 11 (11-1, 11-2) representing a top view and a front view, respectively. The entire area 10 corresponds to the entire area of the paper when the drawing data D10 is printed on paper media.

The drawing element 11 consists of various lines and characters for specifying the shape and dimensions of an assembly or parts. Examples of lines in the drawing element 11 include outline lines, dimension lines, hidden lines, center lines, and imaginary lines. Examples of the characters in the drawing element 11 include dimensions, tolerances, and machining instructions.

The types of drawing elements 11 included in the drawing data D10 are not limited to the top view and the front view shown in FIGS. 2A and 2B and may be other types of drawings, such as side views, back views, bottom views, and cross-sectional views.

The title field 12 is a type of table included in the drawing data D10. The title field 12 has rule lines made up of vertical and horizontal lines and boxes separated by the rule lines. Each box contains characters, and each box has an attribute that defines the characters contained within it. The boxes are also classified by properties that indicate the type of box. The properties include an attribute heading property, serial number heading property, attribute-absent field property, and attribute-present field property.

As shown in FIGS. 2A and 2B, examples of the attribute of the title field 12 include part name, drawing number, scale, date, designer, and approver. The boxes in the title field 12 are classified into three categories: attribute-present field property, attribute-heading property, and attribute-absent field property. The box classified as attribute-present field property contains field characters (in the example in FIG. 2A, “1:2”, “2024/1/11”, “GUIDE A”, “F1-222-33-A”) and attribute characters that define the attributes of the field characters (in the example in FIGS. 2A and 2B, “Scale”, “Date”, “Part name”, and “Drawing number”). The box classified as attribute-heading property contains attribute characters that determine the attributes of the field characters (in the example in FIGS. 2A and 2B, “Designer” and “Approver”). The box classified as attribute-absent field property contains field characters representing the contents of the title field 12 (in the example in FIG. 2A, “AAA” and “BBB”).

The types of tables included in the drawing data D10 are not limited to the title field 12 and may be other types of tables, such as a parts table. In addition, the arrangement and quantity of the boxes that make up each table may be changed as appropriate according to the type of table, and the attributes defined for each box are not limited to the above examples.

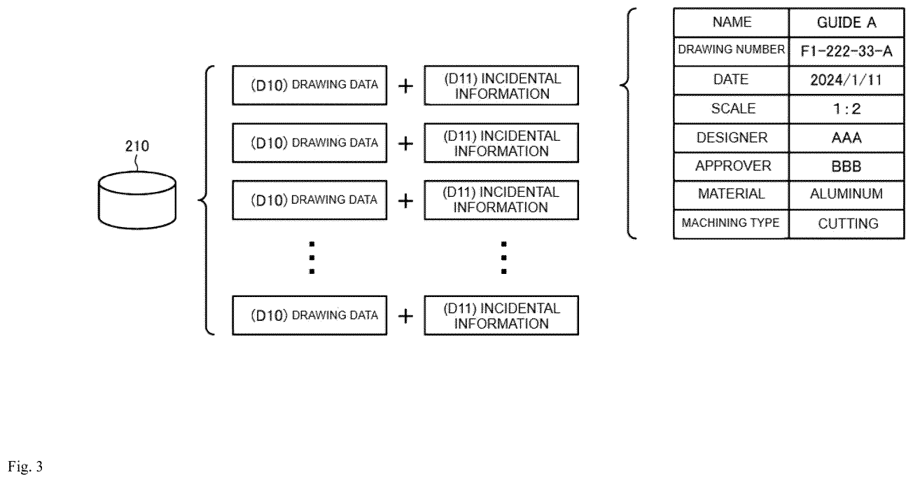

FIG. 3 is a diagram showing an example of the drawing database 210. For each drawing data D10, the drawing data D10 and incidental information D11 related to the drawing data D10 are registered in association with each other in the drawing database 210.

The incidental information D11 is registered in the drawing database 210 by acquiring characters (mainly the field characters) in the overall area 10 by attribute as text data. The incidental information D11 is also registered in the drawing database 210 by acquiring input data by attribute entered by the user via the user terminal device 3. FIG. 3 shows a case where the text data by attribute acquired from the title field 12 included in the drawing data D10 shown in FIGS. 2A and 2B and the input data entered by the user are registered in the drawing database 210 as the incidental information D11.

In the drawing database 210, the incidental information D11 that is registered in association with the drawing data D10 is not limited to the contents of the title field 12 and any information can be associated as necessary. For example, the drawing database 210 may be configured to allow the registration of information based on the drawing element 11 (dimensions, tolerances, machining instructions, etc.) and information related to estimate requests (user name, date and time of estimate, estimate price, etc.), but no limitation is intended.

### Configuration of Drawing Processing Device 2

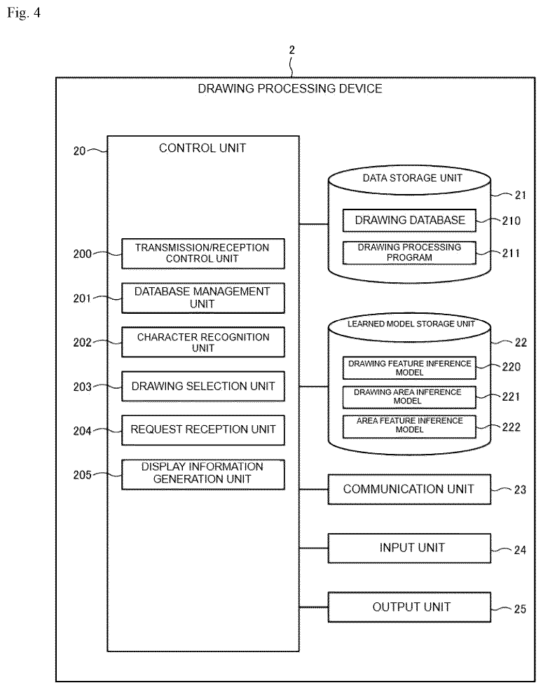

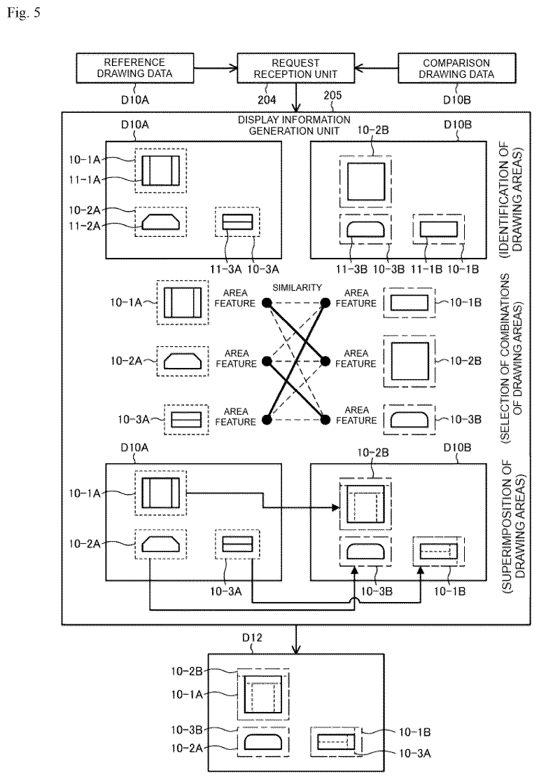

FIG. 4 is a block diagram showing an example of the drawing processing device 2. FIG. 5 is a functional illustration of an example of a request reception unit 204 and a display information generation unit 205. The drawing processing device 2 includes a control unit 20, a data storage unit 21, a learned model storage unit 22, a communication unit 23, an input unit 24, and an output unit 25.

The communication unit 23 is connected to an external device (e.g., the user terminal device 3) via the network 4 and functions as a communication interface for sending and receiving various types of data. The input unit 24 and the output unit 25 function as a user interface by receiving various input operations and outputting various information via a display screen or sound, respectively. Note that, the input unit 24 and the output unit 25 may be omitted.

The data storage unit 21 stores the drawing database 210 and an information processing program 211. As shown in FIG. 3, a plurality of pieces of the drawing data D10 and the incidental information D11 are registered in the drawing database 210 in association with each other. The specific configuration of the drawing database 210 is not limited to the example of FIG. 3 and may be designed as required.

The learned model storage unit 22 stores a drawing feature inference model 220, a drawing area inference model 221, and an area feature inference model 222 as mechanically learned inference models.

The drawing feature inference model 220 infers drawing features for the drawing data D10 when the drawing data D10 is input. The drawing features as the result of inference are output, for example, in vector-format data using a fixed-length numerical array but are not limited to vector format and may be output in other data formats. The drawing feature inference model 220 is subjected to machine learning such that, for example, the more similar the pieces of drawing data D10 are to each other, the similarity when the drawing features are compared increases. The similarity is defined by the distance between the drawing features when they are compared, for example. For the distance between the features, for example, distance indices such as Euclidean distance, Manhattan distance, Chebyshev distance, and Mahalanobis distance, and similarity indices such as cosine similarity can be used. Data after a predetermined pre-processing (size adjustment, etc.) is performed on the drawing data D10 may be input to the drawing feature inference model 220, or the incidental information D11 may be input together with the drawing data D10. Additionally, predetermined post-processing (dimension deletion, etc.) may be performed on a vector of the drawing features output from the drawing feature inference model 220.

The drawing area inference model 221 infers the drawing area surrounding the drawing element 11 in the drawing data D10 when the drawing data D10 is input. In a case where the drawing data D10 (D10A and D10B shown in FIG. 5) contains a plurality of the drawing elements 11 (11-1A to 11-3A and 11-1B to 11-3B shown in FIG. 5), the drawing area inference model 221 infers a plurality of drawing areas (10-1A to 10-3A and 10-1B to 10-3B shown in FIG. 5) that surround each of the plurality of drawing elements 11. The drawing areas are represented by polygons such as quadrilaterals. Thus, the drawing areas as the result of inference are output as data that includes, for example, the coordinates of vertices of the drawing area in a coordinate system when a predetermined coordinate system is set for the overall area 10. The data may be input to the drawing area inference model 221 after a predetermined pre-processing is performed on the drawing data D10.

The area feature inference model 222 infers area features for the data of the drawing area cut out from the drawing data D10 when the data of the drawing area is input. Similar to the drawing features, the area features as the result of inference are output in vector-format data using a fixed-length numerical array, for example, but are not limited to vector format and may be output in other data formats. The area feature inference model 222 is subjected to machine learning such that, for example, the more similar the pieces of drawing data D10 are to each other, the degree of similarity when the drawing features are compared increases. The similarity is defined by the distance between the drawing features when they are compared, for example. For the distance between the features, for example, distance indices such as Euclidean distance, Manhattan distance, Chebyshev distance, and Mahalanobis distance, and similarity indices such as cosine similarity can be used. Similar to the drawing feature inference model 220, data after a predetermined pre-processing (size adjustment, etc.) is performed on the data of the drawing area may be input to the area feature inference model 222, or the incidental information D11 may be input together with the drawing data D10. Additionally, predetermined post-processing (dimension deletion, etc.) may be performed on a vector of the drawing features output from the area feature inference model 222.

The inference models 220 to 222 are all models that use a neural network or the like, but any kind of machine learning models can be used. The quantity of each of the inference models 220 to 222 stored in the learned model storage unit 22 is not limited to one and multiple inference models 220 to 222 with different conditions, such as different machine learning methods or different data, may be stored and used selectively or in parallel with one another.

In FIG. 4, the data storage unit 21 and the learned model storage unit 22 are shown as two storage units, but the data storage unit 21 and the learned model storage unit 22 may comprise a single storage unit or three or more storage units. Further, at least one of the data storage unit 21 and the learned model storage unit 22 may comprise the storage unit of an external computer (e.g., a server-based computer or a cloud-based computer).

The control unit 20 executes the information processing program 211 recorded in the data storage unit 21 to function as a transmission/reception control unit 200, a database management unit 201, a character recognition unit 202, a drawing selection unit 203, a request reception unit 204, and a display information generation unit 205.

### Transmission/Reception Control Unit 200

The transmission/reception control unit 200 transmits/receives various types of data to/from an external device (e.g., the user terminal device 3). For example, the transmission/reception control unit 200 transmits, to the user terminal device 3, display information for outputting various display screens to the user terminal device 3 and receives, from the user terminal device 3, operation information for receiving input operations performed on the display screen of the user terminal device 3. At this time, the transmission/reception control unit 200 coordinates with the units 201 to 204 to transmit the display information to the user terminal device 3 and receives the operation information from the user terminal device 3.

### Database Management Unit 201

The database management unit 201 receives new drawing data D10 from the user terminal device 3 via the transmission/reception control unit 200 and registers the drawing data D10 in the drawing database 210. At that time, the database management unit 201 registers recognition results of characters (text data or position data) recognized from the new drawing data D10 by the character recognition unit 202 and input data input by the user as the incidental information D11 in association with the drawing data D10.

The database management unit 201 reads the drawing data D10 that is registered in the drawing database 210 and transmits display information for displaying the registered drawing data D10 to the user terminal device 3 via the transmission/reception control unit 200. Further, the database management unit 201 modifies the drawing data D10 that is registered in the drawing database 210 when the database management unit 201 receives operation information for editing the drawing data D10 from the user terminal device 3 via the transmission/reception control unit 200.

### Character Recognition Unit 202

The character recognition unit 202 performs character recognition processing of recognizing the characters included in the new drawing data D10. The character recognition unit 202 recognizes the characters included in the drawing data D10 by, for example, performing optical character recognition (OCR) and reading the characters as text data. As the result of character recognition, text data indicating the relevant characters and position data indicating the position where the relevant characters are written are obtained. At this time, the character recognition result may be displayed on the display screen of the user terminal device 3, and editing operations may be performed by the user. In a case where text data is embedded in the drawing data D10, the character recognition unit 202 may recognize the characters contained in the drawing data D10 by reading the text data. Additionally, the character recognition unit 202 may perform character recognition processing on the drawing data D10 that is registered in the drawing database 210.

### Drawing Selection Unit 203

The drawing selection unit 203 receives a designation for reference drawing data D10A, which is drawing data that serves as a reference, from the user terminal device 3 via the transmission/reception control unit 200.

For example, the drawing selection unit 203 displays a display screen on the user terminal device 3 to show a list of the drawing data D10 that is already registered in the drawing database 210 and, when a specific piece of drawing data D10 is selected by the user on the display screen, that piece of drawing data D10 is received as the designation of the reference drawing data D10A. The drawing selection unit 203 also displays a display screen for uploading new drawing data D10 on the user terminal device 3 and, when new drawing data D10 is uploaded on the display screen, the drawing data D10 is received as the designation of the reference drawing data D10A.

The drawing selection unit 203 refers to the drawing database 210 and selects comparison drawing data D10B, which is drawing data D10 to serve as a comparison with the reference drawing data D10A, from a plurality of pieces of candidate drawing data D10 (drawing data D10 that is registered in the drawing database 210). The pieces of candidate drawing data D10 are candidates for the comparative drawing data D10B.

For example, the drawing selection unit 203 calculates the drawing features of the reference drawing data D10A and the candidate drawing data D10, respectively, and selects the comparison drawing data D10B on the basis of similarity when comparing the calculated drawing features of the reference drawing data D10A and the candidate drawing data D10.

### Request Reception Unit 204

The request reception unit 204 receives a comparison request on the basis of the reference drawing data D10A for the designation received by the drawing selection unit 203 and the comparison drawing data D10B selected by the drawing selection unit 203.

The request reception unit 204 may, for example, receive a request from the user terminal device 3 to compare the reference drawing data D10A with the comparison drawing data D10B via the transmission/reception control unit 200. For example, the request reception unit 204 may display a display screen on the user terminal device 3 to show a list of the drawing data D10 that is registered in the drawing database 210 and, when two specific pieces of drawing data D10 are selected by the user on the display screen, may receive a comparison request including the two pieces of drawing data D10 as the reference drawing data D10A and the comparison drawing data D10B.

### Display Information Generation Unit 205

The display information generation unit 205 identifies reference drawing areas 10-1A to 10-3A that surround the drawing elements 11-1A to 11-3A included in the reference drawing data D10A of the comparison request received by the request reception unit 204 and comparison drawing areas 10-1B to 10-3B that surround the drawing elements 11-1B to 11-3B included in the comparison drawing data D10B of the comparison request received by the request reception unit 204, respectively, to thereby generate drawing display information D12 that displays the identified reference drawing areas 10-1A to 10-3A and the comparison drawing areas 10-1B to 10-3B in a superimposed manner.

The display information generation unit 205 transmits the drawing display information D12 generated as described above to the user device terminal 3 via the transmission/reception control unit 200 and displays, on the user terminal device 3, a display screen for comparing the reference drawing data D10A and the comparison drawing data D10B on the basis of the drawing display information D12. The specific method of generating the drawing display information D12 and details of the display screen will be described later.

### Hardware Configuration of Each Device

FIG. 6 is a hardware configuration diagram showing an example of the computer 900. The drawing processing device 2 and the user terminal device 3 in the drawing management system 1 are each configured by a general-purpose or dedicated computer 900.

As shown in FIG. 6, the computer 900 includes, as major components, a bus 910, a processor 912, a memory 914, an input device 916, an output device 917, a display device 918, a storage device 920, a communication interface (I/F) unit 922, an external device IF unit 924, an input/output (I/O) device IF unit 926, and a media I/O unit 928. Note that, the above components may be omitted as appropriate depending on the application in which the computer 900 is used.

The processor 912 is configured by one or more arithmetic processing units (central processing unit (CPU), micro-processing unit (MPU), digital signal processor (DSP), graphics processing unit (GPU), etc.) and operates as a control unit that controls the entire computer 900. The memory 914 stores various data and programs 930, and is configured by a volatile memory (DRAM, SRAM, etc.) that functions as the main memory and a non-volatile memory (ROM) or a flash memory.

The input device 916 is configured by, for example, a keyboard, a mouse, a numeric keypad, an electronic pen, or a microphone, and functions as an input unit. The output device 917 is configured by, for example, a sound (voice) output device or a vibration device, and functions as an output unit. The display device 918 is configured by, for example, a liquid crystal display, an organic EL display, electronic paper, or a projector, and functions as an output unit. The input device 916 and the display device 918 may be configured integrally, for example, as a touch panel display. The storage device 920 is configured by, for example, an HDD, an SSD, and functions as a storage unit. The storage device 920 stores various data necessary for executing the operating system and the program 930.

The communication I/F unit 922 is wired or wirelessly connected to a network 940 such as the Internet or an intranet (which may be the same as the network 4 in FIG. 1) and functions as a communication unit that sends/receives data to/from another computer in accordance with a predetermined communication standard. The external device I/F unit 924 is wired or wirelessly connected to an external device 950 such as a camera, a printer, a scanner, or a reader/writer. Further, the external device I/F unit 924 functions as a communication unit that transmits/receives data to/from the external device 950 in accordance with a predetermined communication standard. The I/O device I/F unit 926 is connected to an I/O device 960 such as a sensor or an actuator, and functions as a communication unit that transmits/receives various signals and data to/from the I/O device 960, such as detection signals by sensors and control signals to actuators. The media I/O unit 928 is configured by a drive device such as a DVD drive or a CD drive, and reads/writes data to/from a medium (non-transient storage media) 970 such as a DVD or a CD.

In the computer 900 having the above configuration, the processor 912 calls and executes the program 930 stored in the storage device 920 to the memory 914 and controls various parts of the computer 900 via the bus 910. The program 930 may be stored in the memory 914 instead of in the storage device 920. The program 930 may be recorded on the medium 970 in an installable file format or an executable file format and may be provided to the computer 900 via the media I/O unit 928. The program 930 may be provided to the computer 900 by being downloaded via the network 940 via the communication I/F unit 922. The computer 900 may also be a hardware realization of various functions realized by the processor 912 executing the program 930, such as, for example, an FPGA or ASIC.

The computer 900 may be configured by, for example, a stationary computer or a portable computer, which may be any form of electronic device. The computer 900 may be a client computer, a server computer, or a cloud computer, or may be an embedded computer referred to as a control board or a controller (including a microcontroller, a programmable logic controller, and a sequencer).

### Operation of Drawing Processing Device 2

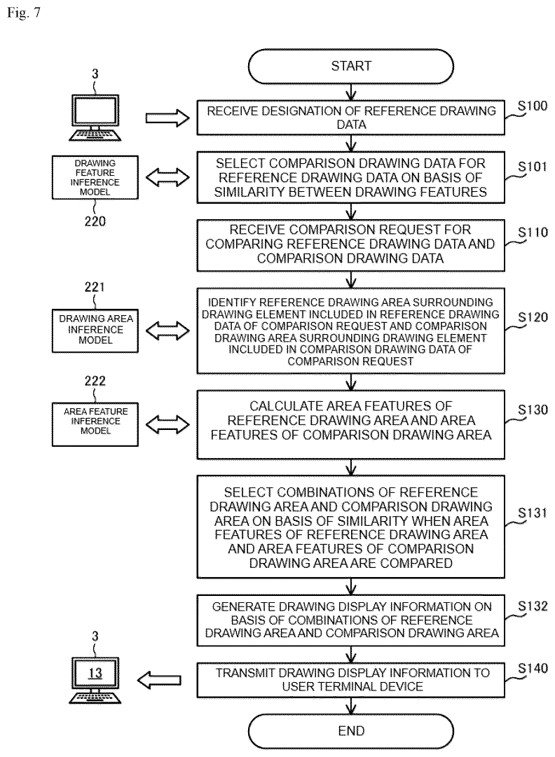

FIG. 7 is a flowchart showing a first operation example of a drawing processing method performed by the drawing processing device 2. In the following description, it is assumed that a plurality of pieces of the drawing data D10 are already registered in the drawing database 210.

First, in step S100 (drawing selection step), the drawing selection unit 203 receives a designation for the reference drawing data D10A when a user selects a specific piece of drawing data D10 as the reference drawing data D10A on the display screen displaying a list of the registered drawing data D10.

Next, in step S101, the drawing selection unit 203 references the drawing database 210 and selects the comparison drawing data D10B to be compared to the reference drawing data D10A for the designation received in step S100.

Specifically, the drawing selection unit 203 inputs the reference drawing data D10A into the drawing feature inference model 220 to acquire the drawing features of the reference drawing data D10A as an inference result of the drawing feature inference model 220. Further, the drawing selection unit 203 inputs each piece of drawing data D10 already registered in the drawing database 210 (hereinafter referred to as “candidate drawing data D10”) into the drawing feature inference model 220 to acquire the drawing features of each piece of candidate drawing data D10 as the inference result of the drawing feature inference model 220. Then, the drawing selection unit 203 calculates the similarity between the drawing features of each piece of candidate drawing data D10 and the drawing features of the reference drawing data D10A and selects, as the comparison drawing data DOB, the candidate drawing data D10 with the highest similarity to the reference drawing data D10A from multiple pieces of candidate drawing data D10.

Next, in step S110 (request reception step), the request reception unit 204 receives a comparison request on the basis of the reference drawing data D10A for the designation received in step S110 and the comparison drawing data D10B selected in step S111.

Next, in step S120 (display information generation step), as shown in FIG. 5, the display information generation unit 205 identifies the reference drawing areas 10-1A to 10-3A that surround the drawing elements 11-1A to 11-3A included in the reference drawing data D10A of the comparison request received in step S110 and the comparison drawing areas 10-1B to 10-3B that surround the drawing elements 11-1A to 11-3A included in the comparison drawing data D10B of the comparison request received in step S110.

Specifically, the display information generation unit 205 inputs the reference drawing data D10A into the drawing area inference model 221 to identify the reference drawing areas 10-1A to 10-3A as the inference result of the drawing area inference model 221. Additionally, the display information generation unit 205 inputs the comparison drawing data D10B into the drawing area inference model 221 to identify the comparison drawing areas 10-1B to 10-3B as the inference result of the drawing area inference model 221.

Next, in step S130, as shown in FIG. 5, the display information generation unit 205 calculates the area features of the reference drawing areas 10-1A to 10-3A identified for the reference drawing data D10A in step S120 and the area features of the comparison drawing areas 10-1B to 10-3B identified for the comparison drawing data D10B in step S120.

Specifically, the display information generation unit 205 inputs the data of the reference drawing areas 10-1A to 10-3A into the area feature inference model 222 to thereby calculate the area features of the reference drawing areas 10-1A to 10-3A as the inference result of the area feature inference model 222. Additionally, the display information generation unit 205 inputs the data of the comparative drawing areas 10-1B to 10-3B into the area feature inference model 222 to calculate the area features of the comparison drawing areas 10-1B to 10-3B as the inference result of the area feature inference model 222.

Next, in step S131, as shown in FIG. 5, the display information generation unit 205 selects combinations of the reference drawing areas 10-1A to 10-3A and the comparison drawing areas 10-1B to 10-3B on the basis of the similarity between the area features of the reference drawing areas 10-1A to 10-3A and the area features of the comparison drawing areas 10-1B to 10-3B calculated in step S130 when compared.

Specifically, the display information generation unit 205 calculates the similarity between random combinations of the reference drawing areas 10-1A to 10-3A and the comparison drawing areas 10-1B to 10-3B by using a round robin of the reference drawing areas 10-1A to 10-3A and the comparison drawing areas 10-1B to 10-3B. Then, the display information generation unit 205 selects combinations of the reference drawing areas 10-1A to 10-3A and the comparison drawing areas 10-1B to 10-3B that increase the similarity. As shown in FIG. 5, in a case where the number of reference drawing areas 10-1A to 10-3A is three and the number of comparison drawing areas 10-1B to 10-3B is three, that is, the numbers are the same as each other, the display information generation unit 205 selects three combinations that maximize the similarity. In FIG. 5, the three combinations selected based on similarity are indicated by solid lines. In a case where the number of reference drawing areas 10-1A to 10-3A is one and the number of comparison drawing areas 10-1B to 10-3B is three, that is, the numbers are different from each other, the display information generation unit 205 selects one combination that maximizes the similarity, favoring the lower number of drawing areas.

Next, in step S132, as shown in FIG. 5, the display information generation unit 205 generates the drawing display information D12 on the basis of the combinations of the reference drawing areas 10-1A to 10-3A and the comparison drawing areas 10-1B to 10-3B selected in step S131.

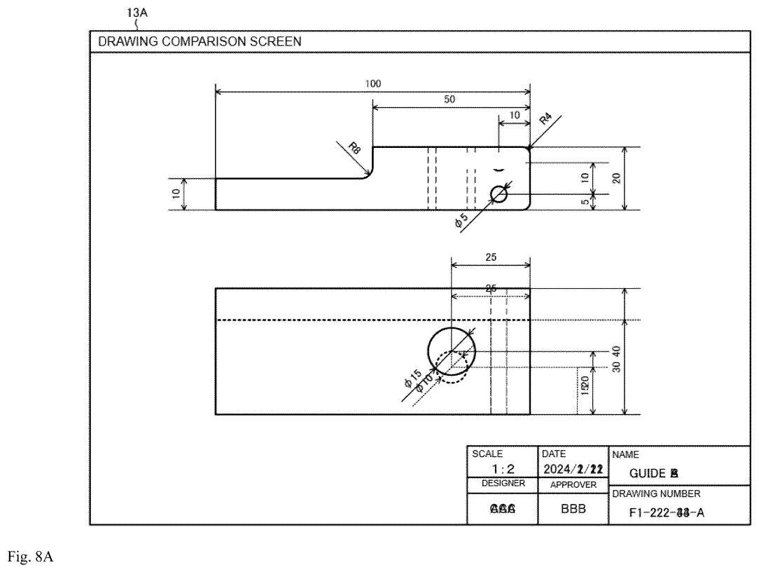

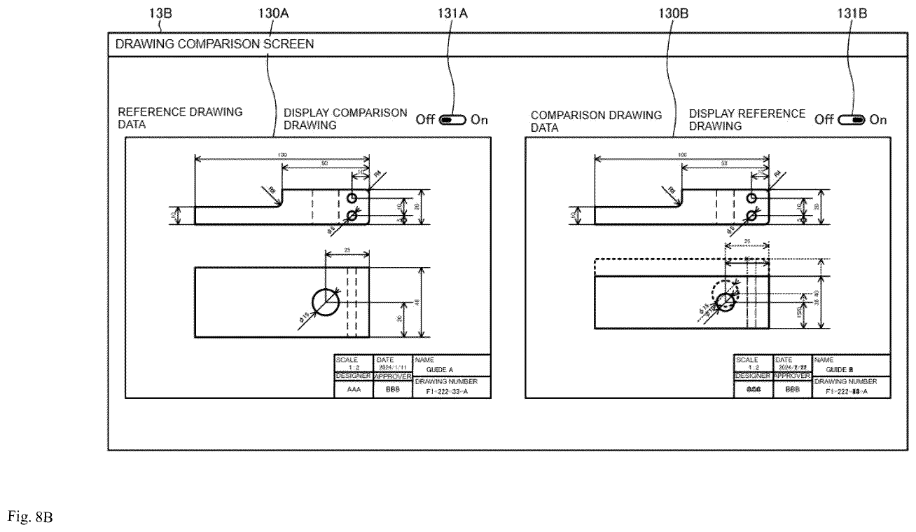

Specifically, the display information generation unit 205 generates the drawing display information D12 that displays a drawing comparison screen 13 (drawing comparison screen 13A shown in FIG. 8A and drawing comparison screen 13B shown in FIG. 8B) to be described below. For example, the display information generation unit 205 generates the drawing display information D12 by aligning the reference drawing areas 10-1A to 10-3A and the comparison drawing areas 10-1B to 10-3B such that the number of overlapping portions increases when the reference drawing areas 10-1A to 10-3A and the comparison drawing areas 10-1B to 10-3B are superimposed.

For example, a phase limited correlation method is used to align the reference drawing areas 10-1A to 10-3A and the comparison drawing areas 10-1B to 10-3B, but any method can be used. Aligning the reference drawing areas 10-1A to 10-3A and the comparison drawing areas 10-1B to 10-3B highlights differences other than the common overlapping areas between the lines and characters comprising the drawing elements 11-1A to 11-3A and the lines and characters comprising the drawing elements 11-1A to 11-3A, which can then be extracted.

At this time, in a case where the number of combinations selected in step S131 is more than 1, as shown in FIG. 5, the display information generation unit 205 generates the drawing display information D12 by aligning the reference drawing areas 10-1A to 10-3A and the comparison drawing areas 10-1B to 10-3B for each combination. As a result, even if the positions of the drawing elements 11 selected for the combination in the reference drawing data D10A and the comparison drawing data D10B are out of alignment, the differences between the drawing elements 11 in each drawing area are easily visible when compared because alignment is performed for each combination.

When aligning the reference drawing areas 10-1A to 10-3A and the comparison drawing areas 10-1B to 10-3B, the display information generation unit 205 may perform deformation processing such as enlargement, reduction, or rotation on at least one of the reference drawing areas 10-1A to 10-3A and the comparison drawing areas 10-1B to 10-3B. The deformation processing is performed, for example, on the basis of the dimensions described in the reference drawing areas 10-1A to 10-3A and the comparison drawing areas 10-1B to 10-3B and the scale stored as the incidental information D11.

Then, in step S140, the display information generation unit 205 transmits the drawing display information D12 generated in step S132 to the user terminal device 3 via the transmission/reception control unit 200. As a result, the drawing comparison screen 13 for comparing the reference drawing data D10A and the comparison drawing data D10B is displayed on the user terminal device 3 on the basis of the drawing display information D12.

FIG. 8A is a diagram showing a first display example of the drawing comparison screen 13A. FIG. 8A shows a case where the drawing data D10 shown in FIGS. 2A and 2B is designated as the reference drawing data D10A and the comparison drawing data D10B.

The drawing comparison screen 13A is a display screen that displays two reference drawing areas in the reference drawing data D10A (the drawing data D10 shown in FIG. 2A) and two comparison drawing areas in the comparison drawing data D10B (the drawing data D10 shown in FIG. 2B) superimposed over each other. The two drawing elements 11-1 and 11-2 included in the reference drawing data D10A and the two drawing elements 11-1 and 11-2 included in the comparison drawing data D10B are displayed in different forms. For example, the color, type, or thickness of the lines and characters may be changed, and this can be specified by the user. The two drawing elements 11-1 included in the reference drawing data D10A and the two drawing elements 11-1 and 11-2 included in the comparison drawing data D10B may be set in the foreground or background.

When the two drawing elements 11-1 and 11-2 included in the reference drawing data D10A and the two drawing elements 11-1 and 11-2 included in the comparison drawing data D10B are superimposed, the overlapping portions are displayed in a first display form, of the differences other than the overlapping portions, the two drawing elements 11-1 and 11-2 included in the reference drawing data D10A are displayed in a second display form, and of the differences other than the overlapping portions, the two drawing elements 11-1 and 11-2 included in the comparative drawing data D10B are displayed in a third display form. The first, second, and third display forms may be different from each other. The positional relationship when the reference drawing area and the comparison drawing area are superimposed may be changed by the user by operating buttons (not shown) that specify up, down, left, and right, or a dragging operation performed on the drawing comparison screen 13A.

FIG. 8B is a diagram showing a second display example of the drawing comparison screen 13B. Similar to FIG. 8A, FIG. 8B shows a case where the drawing data D10 shown in FIGS. 2A and 2B is designated as the reference drawing data D10A and the comparison drawing data D10B.

The drawing comparison screen 13B includes a reference drawing data display area 130A for displaying the reference drawing data D10A (the drawing data D10 shown in FIG. 2A), a comparison drawing data display area 130B for displaying the comparison drawing data D10B (the drawing data D10 shown in FIG. 2B), a comparison drawing display setting button 131A for setting ON/OFF to indicate whether the comparison drawing data D10B is superimposed on the reference drawing data display area 130A, and a reference drawing display setting button 131B for setting ON/OFF to indicate whether the reference drawing data D10A is superimposed on the comparison drawing data display area 130B.

When the comparison drawing display setting button 131A is set to ON, the two drawing elements 11-1 and 11-2 included in the comparison drawing area are superimposed on the two drawing elements 11-1 and 11-2 included in the reference drawing area displayed in the reference drawing data display area 130A.

When the reference drawing display setting button 131B is set to ON, the two drawing elements 11-1 and 11-2 included in the reference drawing area are superimposed on the two drawing elements 11-1 and 11-2 included in the comparison drawing area displayed in the comparison drawing data display area 130B.

The reference drawing data display area 130A and the comparison drawing data display area 130B are displayed in different display forms, similar to the drawing comparison screen 13A shown in FIG. 8A. In FIG. 8B, the reference drawing data display area 130A and the comparison drawing data display area 130B are arranged side by side in the left-right direction but may be arranged side by side in the up-down direction. The size of the reference drawing data display area 130A and the size of the comparison drawing data display area 130B may be different. Furthermore, one of the comparison drawing display setting button 131A and the reference drawing display setting button 131B may be omitted.

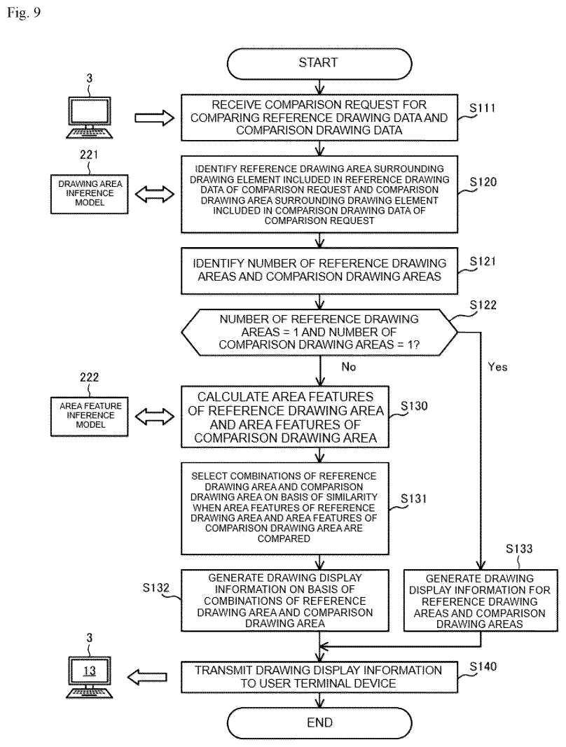

FIG. 9 is a flowchart showing a second operation example of the drawing processing method performed by the drawing processing device 2. The following description will focus on differences with the flowchart of FIG. 7.

First, in step S111 (request reception step), the request reception unit 204 receives a comparison request for comparing the reference drawing data D10A and the comparison drawing data D10B when the user selects two specific pieces of the drawing data D10 as the reference drawing data D10A and the comparison drawing data D10B on the display screen that displays a list of the registered drawing data D10.

Next, in step S120 (display information generation step), as shown in FIG. 5, the display information generation unit 205 identifies the reference drawing areas 10-1A to 10-3A that surround the drawing elements 11 included in the reference drawing data D10A of the comparison request received in step S111 and the comparison drawing areas 10-1B to 10-3B that surround the drawing elements 11 included in the comparison drawing data D10B of the comparison request received in step S110.

Next, in step S121, the display information generation unit 205 identifies the number of reference drawing areas 10-1A to 10-3A (“3” in the example in FIG. 5) identified for the reference drawing data D10A in step S120 and the number of comparison drawing areas 10-1B to 10-3B (“3” in the example in FIG. 5) identified for the comparison drawing data D10B in step S120.

Next, in step S122, the display information generation unit 205 determines whether the number of reference drawing areas 10-1A to 10-3A and the number of comparison drawing areas 10-1B to 10-3B identified in step S121 are both “1”.

As a result, in a case where the display information generation unit 205 determines that the number of reference drawing areas 10-1A to 10-3A and the number of comparison drawing areas 10-1B to 10-3B are both “1” (Yes in step S122), the processing proceeds to step S133. In step S133, the display information generation unit 205 generates the drawing display information D12 for the one reference drawing area identified in step S120 and the one comparison drawing area identified in step S120.

On the other hand, in a case where the display information generation unit 205 determines that at least one of the number of reference drawing areas 10-1A to 10-3A and the number of comparison drawing areas 10-1B to 10-3B is more than 1 (No in step S122), the processing proceeds to steps S130 to S132 to generate the drawing display information D12 in the same manner as in the flowchart of FIG. 7. In the example of FIG. 5, “No” is determined in step S122.

Then, in step S140, the display information generation unit 205 transmits the drawing display information D12 generated in step S132 or step S133 to the user terminal device 3 via the transmission/reception control unit 200. As a result, the drawing comparison screen 13 for comparing the reference drawing data D10A and the comparison drawing data D10B is displayed on the user terminal device 3 on the basis of the drawing display information D12.

As described above, with the drawing processing device 2 and the drawing processing method according to this embodiment, the reference drawing area surrounding the drawing elements 11 included in the reference drawing data D10A and the comparison drawing area surrounding the drawing elements 11 included in the comparison drawing data D10B are identified, and the drawing display information D12 is generated to superimpose the reference drawing area and the comparison drawing area such that the differences between the two drawing data D10 can be easily seen when the drawing data D10 are compared.

### Other Embodiments

The present invention is not limited to the embodiments described above and can be implemented with various modifications within the scope that does not depart from the main purpose of the invention. All such modifications are included in the technical concept of the present invention.

In the above-described embodiments, the drawing processing device 2 consists of a single device, but the drawing processing device 2 may also consist of multiple devices. For example, the drawing processing device 2 may include units 202 to 205 that are distributed across multiple devices. With this configuration, each unit (each step) provided by each of the above devices may be realized by a program executable by the computer 900.

In the above-described embodiments, a case is described where the drawing processing device 2 operates according to the flowchart of FIG. 7 or FIG. 9, but the order of the steps of the flowchart may be changed or steps may be omitted as appropriate. For example, in the flowchart of FIG. 9, steps S100 to S110 may be executed in place of step S111 to receive the comparison request for comparing the reference drawing data D10A and the comparison drawing data D10B.

In the above-described embodiments, a case is described where the drawing processing device 2 generates the drawing display information D12 of the comparison request for comparing the reference drawing data D10A and the comparison drawing data D10B. However, the user terminal device 3 may include the units 200 to 205 of the drawing processing device 2 to function as the drawing processing device 2.

### REFERENCE SIGNS LIST

1 Drawing management system
2 Drawing processing device
3 User terminal device
20 Control unit
21 Data storage unit
22 Learned model storage unit
23 Communication unit
24 Input unit
25 Output unit
200 Transmission/reception control unit
201 Database management unit
202 Character recognition unit
203 Drawing selection unit
204 Request reception unit
205 Display information generation unit
210 Drawing database
211 Drawing processing program

1. A drawing processing device for processing drawing data including one or more drawing elements that specify a shape or dimensions of a target object, the drawing processing device comprising:
a request reception unit configured to receive a comparison request for comparing reference drawing data being the drawing data that serves as a reference and comparison drawing data being the drawing data to be compared to the reference drawing data; and
a display information generation unit configured to identify a reference drawing area surrounding the drawing element included in the reference drawing data of the comparison request received by the request reception unit and a comparison drawing area surrounding the drawing element included in the comparison drawing data of the comparison request received by the request reception unit, to thereby generate drawing display information for displaying the identified reference drawing area and the identified comparison drawing area in a superimposed manner, wherein
the display information generation unit
calculates an area feature of the reference drawing area identified for the reference drawing data and an area feature of the comparison drawing area identified for the comparison drawing data,
selects combinations of the reference drawing area and the comparison drawing area on the basis of a similarity between the calculated area feature of the reference drawing area and the calculated area feature of the comparison drawing area when compared, and
generates the drawing display information on the basis of the selected combinations of the reference drawing area and the comparison drawing area.

2. A drawing processing device for processing drawing data including one or more drawing elements that specify a shape or dimensions of a target object, the drawing processing device comprising:
a request reception unit configured to receive a comparison request for comparing reference drawing data being the drawing data that serves as a reference and comparison drawing data being the drawing data to be compared to the reference drawing data; and
a display information generation unit configured to identify a reference drawing area surrounding the drawing element included in the reference drawing data of the comparison request received by the request reception unit and a comparison drawing area surrounding the drawing element included in the comparison drawing data of the comparison request received by the request reception unit, to thereby generate drawing display information for displaying the identified reference drawing area and the identified comparison drawing area in a superimposed manner, wherein
the display information generation unit is further configured to
identify a number of the reference drawing areas identified for the reference drawing data and a number of the comparison drawing areas identified for the comparison drawing data,
in a case where the number of the identified reference drawing areas and the number of the identified comparison drawing areas are both 1, generate the drawing display information for the reference drawing area identified for the reference drawing data and the comparison drawing area identified for the comparison drawing data,
in a case where at least one of the number of the identified reference drawing areas and the number of the identified comparison drawing areas is more than 1, calculate area features of the reference drawing areas identified for the reference drawing data and area features of the comparison drawing areas identified for the comparison drawing data,
select combinations of the reference drawing area and the comparison drawing area on the basis of a similarity between the calculated area feature of the reference drawing area and the calculated area feature of the comparison drawing area when compared, and
generate the drawing display information on the basis of the selected combinations of the reference drawing area and the comparison drawing area.

3. The drawing processing device according to claim 1, wherein the display information generation unit generates the drawing display information by aligning the reference drawing area and the comparison drawing area for each of the combinations such that the number of overlapping portions increases when the reference drawing area and the comparison drawing area are superimposed.

4. The drawing processing device according to claim 1, wherein
the display information generation unit generates the drawing display information for displaying a drawing comparison screen in which a reference drawing data display area for displaying the reference drawing data and a comparison drawing data display area for displaying the comparison drawing data are arranged side by side, and
the drawing comparison screen
displays the drawing element included in the reference drawing area superimposed on the drawing element included in the comparison drawing area displayed in the comparison drawing data display area, or
displays the drawing element included in the comparison drawing area superimposed on the drawing element included in the reference drawing area displayed in the reference drawing data display area.

5. The drawing processing device according to claim 1, further comprising
a drawing selection unit configured to receive a designation for the reference drawing data and select the comparison drawing data from a plurality of pieces of candidate drawing data being candidates for the comparison drawing data, wherein
the drawing selection unit
calculates drawing features of the reference drawing data and drawing features of the candidate drawing data, and
selects the comparison drawing data on the basis of a similarity between the calculated drawing features of the reference drawing data and the calculated drawing features of the candidate drawing data, and
the request reception unit receives the comparison request on the basis of the reference drawing data related to the designation received by the drawing selection unit and the comparison drawing data selected by the drawing selection unit.

6. A drawing processing method to be executed by a computer for processing drawing data including one or more drawing elements that specify a shape or dimensions of a target object, the drawing processing method comprising:
a request reception step of receiving a comparison request for comparing reference drawing data being the drawing data that serves as a reference and comparison drawing data being the drawing data to be compared to the reference drawing data; and
a display information generation step of identifying a reference drawing area surrounding the drawing element included in the reference drawing data of the comparison request received in the request reception step and a comparison drawing area surrounding the drawing element included in the comparison drawing data of the comparison request received in the request reception step, to thereby generate drawing display information for displaying the identified reference drawing area and the identified comparison drawing area in a superimposed manner, wherein
the display information generation step comprises
calculating an area feature of the reference drawing area identified for the reference drawing data and an area feature of the comparison drawing area identified for the comparison drawing data,
selecting combinations of the reference drawing area and the comparison drawing area on the basis of a similarity between the calculated area feature of the reference drawing area and the calculated area feature of the comparison drawing area when compared, and
generating the drawing display information on the basis of the selected combinations of the reference drawing area and the comparison drawing area.

7. A drawing processing method to be executed by a computer for processing drawing data including one or more drawing elements that specify a shape or dimensions of a target object, the drawing processing method comprising:
a request reception step of receiving a comparison request for comparing reference drawing data being the drawing data that serves as a reference and comparison drawing data being the drawing data to be compared to the reference drawing data; and
a display information generation step of identifying a reference drawing area surrounding the drawing element included in the reference drawing data of the comparison request received in the request reception step and a comparison drawing area surrounding the drawing element included in the comparison drawing data of the comparison request received in the request reception step, to thereby generate drawing display information for displaying the identified reference drawing area and the identified comparison drawing area in a superimposed manner, wherein
the display information generation step comprises
identifying a number of the reference drawing areas identified for the reference drawing data and a number of the comparison drawing areas identified for the comparison drawing data,
in a case where the number of the identified reference drawing areas and the number of the identified comparison drawing areas are both 1, generating the drawing display information for the reference drawing area identified for the reference drawing data and the comparison drawing area identified for the comparison drawing data,
in a case where at least one of the number of the identified reference drawing areas and the number of the identified comparison drawing areas is more than 1, calculating area features of the reference drawing areas identified for the reference drawing data and area features of the comparison drawing areas identified for the comparison drawing data,
selecting combinations of the reference drawing area and the comparison drawing area on the basis of a similarity between the calculated area feature of the reference drawing area and the calculated area feature of the comparison drawing area when compared, and
generating the drawing display information on the basis of the selected combinations of the reference drawing area and the comparison drawing area.
